(19) United States
(12) Patent Application Publication
(10) Pub. No.: US 2025/0311108 A1
(43) Pub. Date: Oct. 2, 2025

(54) Sensor Module

(71) Applicant: SEIKO EPSON CORPORATION, Tokyo (JP)

(72) Inventor: Shinji NISHIO, Suwa (JP)

(21) Appl. No.: 19/095,360

(22) Filed: Mar. 31, 2025

(30) Foreign Application Priority Data
Apr. 1, 2024 (JP) 2024-058764

(51) Int. Cl. H05K 1/18; G01P 1/02; G01P 3/14; G01P 15/18

(52) U.S. Cl. CPC H05K 1/189; G01P 1/023; G01P 1/026; G01P 3/14; G01P 15/18; H05K 2201/10068; H05K 2201/10151; H05K 2201/10189; H05K 2201/10522; H05K 2201/10537; H05K 2201/10545

(57) ABSTRACT

A sensor module includes a first inertial sensor device group including a first inertial sensor device, a second inertial sensor device, and a third inertial sensor device, and a base including a first placement surface on which the first inertial sensor device is disposed, a second placement surface parallel to the first placement surface, on which the second inertial sensor device is disposed, and a third placement surface parallel to the first placement surface, on which the third inertial sensor device is disposed.

The present application is based on, and claims priority from JP Application Serial Number 2024-058764, filed Apr. 1, 2024, the disclosure of which is hereby incorporated by reference herein in its entirety.

### BACKGROUND

### 1. Technical Field

The present disclosure relates to a sensor module.

### 2. Related Art

A sensor device described in JP-A-2019-163955 includes a circuit board, and two X-axis angular velocity sensor devices, two Y-axis angular velocity sensor devices, and two Z-axis angular velocity sensor devices mounted on the circuit board. An X-axis angular velocity is obtained from an average value of output signals of the respective X-axis angular velocity sensor devices, a Y-axis angular velocity is obtained from an average value of output signals of the respective Y-axis angular velocity sensor devices, a Z-axis angular velocity is obtained from an average value of output signals of the respective Z-axis angular velocity sensor devices, and thereby, noise is reduced and detection accuracy of the angular velocities around the respective axes is improved.

JP-A-2019-163955 is an example of the related art.

However, in the configuration of the sensor device in JP-A-2019-163955, since the X-axis angular velocity sensor devices are mounted on side surfaces of the plate-shaped circuit board, it is difficult to juxtapose a plurality of X-axis angular velocity sensor devices in parallel to one another on the circuit board. The same applies to the Y-axis angular velocity sensor devices.

### SUMMARY

A sensor module according to an aspect of the present disclosure includes a first inertial sensor device group including a first inertial sensor device, a second inertial sensor device, and a third inertial sensor device having detection axes in the same direction as one another, and a base including a first placement surface on which the first inertial sensor device is disposed, a second placement surface parallel to the first placement surface, on which the second inertial sensor device is disposed, and a third placement surface parallel to the first placement surface, on which the third inertial sensor device is disposed. A sensor module according to an aspect of the present disclosure includes a first inertial sensor device group including a first inertial sensor device, a second inertial sensor device, and a third inertial sensor device, and a base including a first placement surface on which the first inertial sensor device is disposed, a second placement surface parallel to the first placement surface, on which the second inertial sensor device is disposed, and a third placement surface parallel to the first placement surface, on which the third inertial sensor device is disposed, wherein the first placement surface, the second placement surface, and the third placement surface are arranged along a normal direction of the first placement surface.

### BRIEF DESCRIPTION OF THE DRAWINGS

FIG. 1 is a cross-sectional view showing a sensor module according to a first embodiment.

FIG. 2 is a top view showing inside of the sensor module shown in FIG. 1.

FIG. 3 is a development view of a sensor mounting substrate.

FIG. 4 is a cross-sectional view showing housing of the sensor mounting substrate in a base.

FIG. 5 is a cross-sectional view showing directions of detection axes of respective inertial sensor devices housed in the base.

FIG. 6 shows a modification example of the sensor module shown in FIG. 1.

FIG. 7 shows a modification example of the sensor module shown in FIG. 1.

FIG. 8 shows a modification example of the sensor module shown in FIG. 1.

FIG. 9 shows a modification example of the sensor module shown in FIG. 1.

FIG. 10 shows a modification example of the sensor module shown in FIG. 1.

FIG. 11 is a cross-sectional view showing a sensor module according to a second embodiment.

FIG. 12 is a cross-sectional view showing a sensor module according to a third embodiment.

FIG. 13 is a front view of a first positioning portion.

FIG. 14 is a top view showing a sensor module according to a fourth embodiment.

FIG. 15 is a cross-sectional view of the sensor module shown in FIG. 14.

FIG. 16 is a cross-sectional view of the sensor module shown in FIG. 14.

FIG. 17 is a development view of a sensor mounting substrate.

FIG. 18 is a top view showing a sensor module according to a fifth embodiment.

FIG. 19 shows a development view of a sensor mounting substrate.

### DESCRIPTION OF EMBODIMENTS

As below, a sensor module of the present disclosure will be described in detail based on embodiments shown in the accompanying drawings. Note that, for convenience of description, three axes orthogonal to one another are shown as an X axis, a Y axis, and a Z axis in the respective drawings. Hereinafter, for convenience of description, a direction parallel to the X axis is also referred to as “X-axis direction”, a direction parallel to the Y axis is also referred to as “Y-axis direction”, and a direction parallel to the Z axis is also referred to as “Z-axis direction”. Further, the arrow side in the Z-axis direction is also referred to as “upper”, and the opposite side is also referred to as “lower”. In addition, “parallel” in the specification refers not only to a case where objects are parallel to each other but also to a case where objects are deviated from being parallel to each other within a range in which the objects can be regarded as being parallel to each other in a technical common sense in consideration of dimensional errors s that may occur in manufacturing, tolerances permitted in an apparatus, and the like. Similarly, “orthogonal” refers not only to a case where objects are orthogonal to each other but also to a case where objects are deviated from being orthogonal to each other within a range in which the objects can be regarded as being orthogonal to each other in a technical common sense in consideration of dimensional errors that may occur in manufacturing, tolerances permitted in an apparatus, and the like.

### First Embodiment

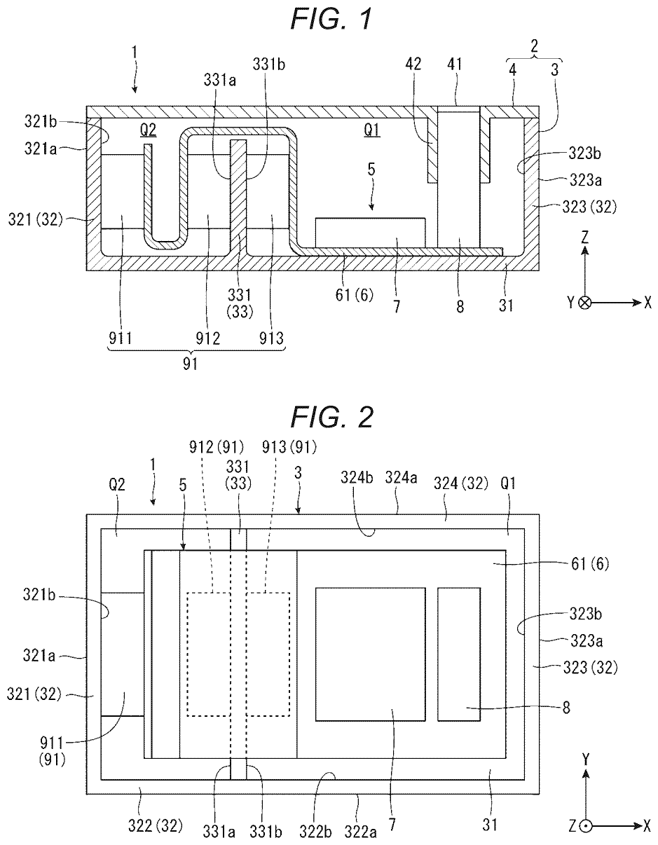

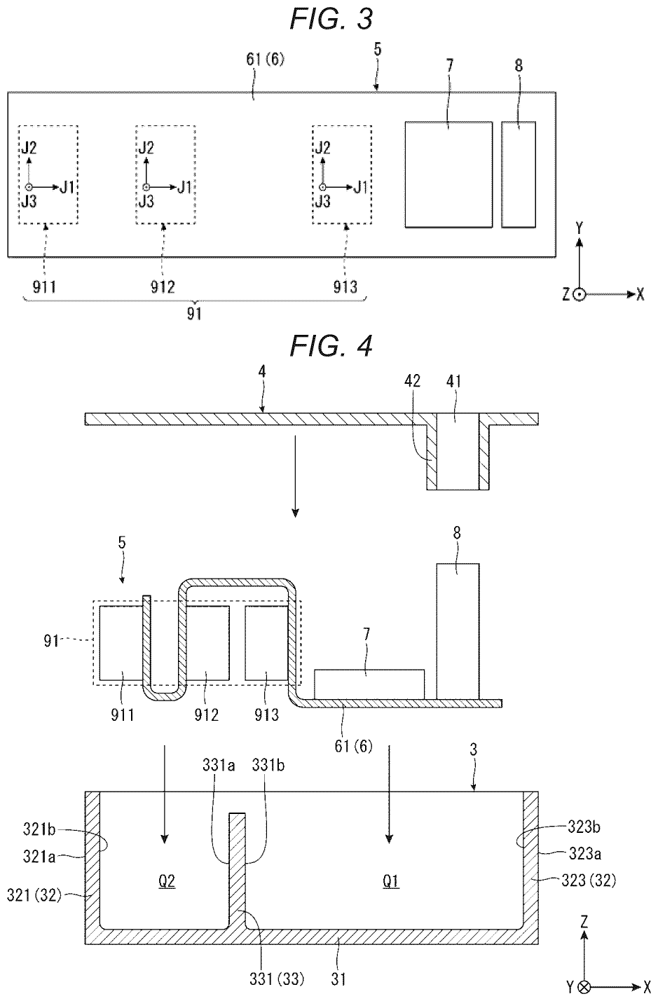

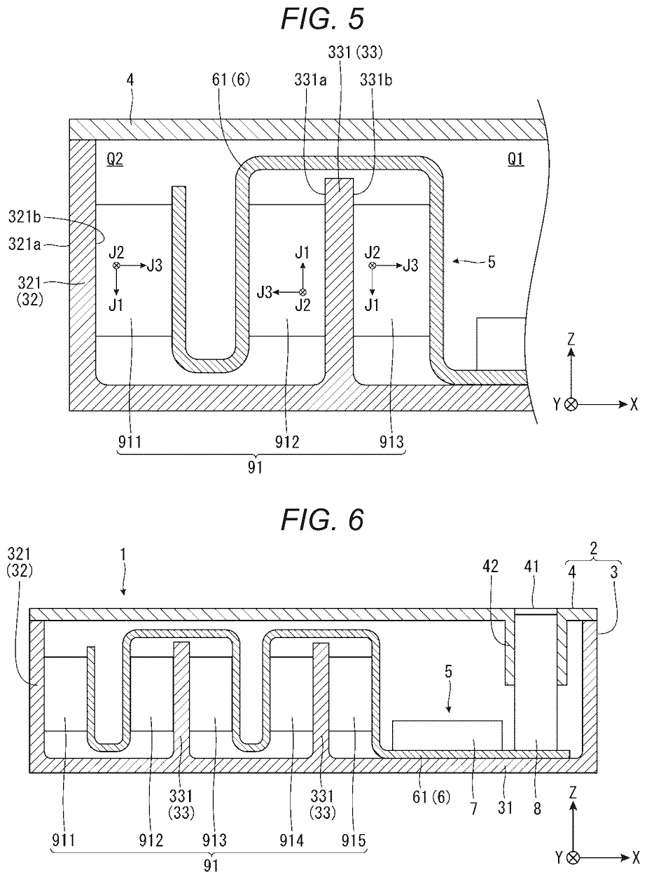

FIG. 1 is a cross-sectional view showing a sensor module according to a first embodiment. FIG. 2 is a top view showing inside of the sensor module shown in FIG. 1. FIG. 3 is a development view of a sensor mounting substrate. FIG. 4 is a cross-sectional view showing housing of the sensor mounting substrate in a base. FIG. 5 is a cross-sectional view showing directions of detection axes of respective inertial sensor devices housed in the base. FIGS. 6 to 10 respectively shows modification examples of the sensor module shown in FIG. 1.

A sensor module 1 shown in FIG. 1 includes a package 2 and a sensor mounting substrate 5 housed in the package 2.

### Package 2

As shown in FIG. 1, the package 2 includes a box-shaped base 3 having an opening in the upper surface, and a plate-shaped lid 4 joined to the upper surface of the base 3 and closing the opening of the base 3. The base 3 and the lid 4 can be respectively formed using a metal material such as aluminum or stainless steel, a ceramic material such as alumina, or the like. However, the constituent materials of the base 3 and the lid 4 are not particularly limited.

As shown in FIGS. 1 and 2, the base 3 includes a rectangular plate-shaped bottom portion 31 and a rectangular frame-shaped outer wall portion 32 stood upward from the outer edge of the bottom portion 31. As shown in FIG. 2, the outer wall portion 32 includes a first outer wall portion 321 located at the minus side in the X-axis direction and extending in the Y-axis direction, a second outer wall portion 322 located at the minus side in the Y-axis direction and extending in the X-axis direction, a third outer wall portion 323 located at the plus side in the X-axis direction and extending in the Y-axis direction, and a fourth outer wall portion 324 located at the plus side in the Y-axis direction and extending in the X-axis direction.

The first outer wall portion 321 as a first wall portion has a pair of wall surfaces 321a and 321b in a front and back relationship, one wall surface 321a (at the minus side in the X-axis direction) faces the outside of the base 3, and the other wall surface 321b (at the plus side in the X-axis direction) faces the inside of the base 3. Further, the second outer wall portion 322 has a pair of wall surfaces 322a and 322b in a front and back relationship, one wall surface 322a (at the minus side in the Y-axis direction) faces the outside of the base 3, and the other wall surface 322b (at the plus side in the Y-axis direction) faces the inside of the base 3.

Furthermore, the third outer wall portion 323 has a pair of wall surfaces 323a and 323b in a front and back relationship, one wall surface 323a (at the plus side in the X-axis direction) faces the outside of the base 3, and the other wall surface 323b (at the minus side in the X-axis direction) faces the inside of the base 3. Moreover, the fourth outer wall portion 324 has a pair of wall surfaces 324a and 324b in a front and back relationship, one wall surface 324a (at the plus side in the Y-axis direction) faces the outside of the base 3, and the other wall surface 324b (at the minus side in the Y-axis direction) faces the inside of the base 3.

As shown in FIG. 1, the base 3 includes an inner wall portion 33 stood upward from the bottom portion 31 and located inside the outer wall portion 32. Further, as shown in FIG. 2, the inner wall portion 33 includes a first inner wall portion 331 extending in the Y-axis direction with one end portion (at the minus side in the Y-axis direction) coupled to the second outer wall portion 322 and the other end portion (at the plus side in the Y-axis direction) coupled to the fourth outer wall portion 324. The first inner wall portion 331 is disposed to be biased toward the first outer wall portion 321 side with respect to the center of the base 3, and divides the inside of the base 3 into a large region Q1 at the plus side in the X-axis direction and a small region Q2 at the minus side in the X-axis direction. The first inner wall portion 331 as a second wall portion has a pair of wall surfaces 331a and 331b in a front and back relationship, and both face the inside of the base 3. One wall surface 331a (at the minus side in the X-axis direction) faces the first outer wall portion 321, and the other wall surface 331b (at the plus side in the X-axis direction) faces the third outer wall portion 323.

Here, each of the three wall surfaces 321b, 331a, and 331b arranged along the X-axis direction includes a Y-Z plane orthogonal to the X axis. That is, the wall surfaces 321b, 331a, and 331b are parallel to one another. Inertial sensor devices 911, 912, and 913 are disposed on the wall surface 321b as a first placement surface, the wall surface 331a as a second placement surface, and the wall surface 331b as a third placement surface, respectively. The base 3 is formed into a shape having the outer wall portion 32 and the inner wall portion 33, and thereby, the wall surfaces 321b, 331a, and 331b can be formed with a simple configuration. In particular, since the wall surfaces 321b, 331a, and 331b are arranged in the X-axis direction, that is, along the normal direction of the wall surface 321b, the inertial sensor devices 911, 912, and 913 can be arranged in a row close to one another. Therefore, the inertial detection accuracy of the sensor module 1 can be increased, and the sensor module 1 can be downsized.

As shown in FIG. 1, the lid 4 has a flat plate shape and is joined to the upper surface of the base 3. A method of joining the lid 4 to the base 3 is not particularly limited. For example, screwing or bonding can be used. Further, the lid 4 has an opening 41 for exposing a connector 8, which will be described later, and a frame-shaped wall portion 42 projecting from the periphery of the opening 41 downward into the base 3 and surrounding the connector 8.

As above, the package 2 is described. However, the configuration of the package 2 is not particularly limited. For example, the shape of the base 3 in a plan view is not limited to the rectangle. For example, at least one end of the first inner wall portion 331 is not necessarily coupled to the outer wall portion 32. Further, the opening for exposing the connector 8 may be formed in the bottom portion 31 or the outer wall portion 32 of the base 3 instead of the lid 4.

### Sensor Mounting Substrate 5

FIG. 3 shows a development view of the sensor mounting substrate 5. As shown in the drawing, the sensor mounting substrate 5 includes a circuit element 7, the connector 8, a first inertial sensor device group 91, and a coupling portion 6 coupling these components. The first inertial sensor device group 91 includes, as the three inertial sensor devices, the inertial sensor device 911 as a first inertial sensor device, the inertial sensor device 912 as a second inertial sensor device, and the inertial sensor device 913 as a third inertial sensor device.

The coupling portion 6 is a flexible wiring board 61 having a strip shape extending in the X-axis direction and flexibility. The circuit element 7, the connector 8, and the inertial sensor devices 911, 912, and 913 are respectively mounted in predetermined positions of the flexible wiring board 61, and further, these are electrically coupled via wiring (not illustrated) formed on the flexible wiring board 61. Specifically, the circuit element 7 and the connector 8 are mounted on the front surface of the flexible wiring board 61, and the inertial sensor devices 911, 912, and 913 are mounted on the back surface. The inertial sensor devices 911, 912, and 913 are disposed in juxtaposition in the X-axis direction. The respective inertial sensor devices 911, 912, and 913 and the circuit element 7 are electrically coupled via the wiring, and the circuit element 7 and the connector 8 are electrically coupled via the wiring. As described above, the circuit element 7, the connector 8, and the respective inertial sensor devices 911, 912, and 913 are mounted on the flexible wiring board 61, and thereby, the respective components are not separated and the respective components are easily attached to the base 3.

The inertial sensor devices 911, 912, and 913 have the same configuration. Each of the inertial sensor devices 911, 912, and 913 is a 6DoF (Six-degrees of freedom) sensor, and can independently detect angular velocities around a J1 axis, a J2 axis, and a J3 axis as three axes orthogonal to one another and accelerations in directions of the J1 axis, the J2 axis, and the J3 axis.

Although not illustrated, each of the inertial sensor devices 911, 912, and 913 includes an angular velocity sensor element that detects the angular velocity around the J1 axis, an angular velocity sensor element that detects the angular velocity around the J2 axis, an angular velocity sensor element that detects an angular velocity around the J3 axis, an acceleration sensor element that detects the acceleration in the J1 axis direction, an acceleration sensor element that detects the acceleration in the J2 axis direction, an acceleration sensor element that detects the acceleration in the J3 axis direction, a control circuit such as a microcontroller that controls driving of each sensor element, and a package that houses these components.

Each of the angular velocity sensor elements and acceleration sensor elements is, for example, a quartz crystal resonator or a silicon MEMS (Micro Electric Mechanical Device). The control circuit includes, for example, a drive circuit that drives each sensor element, a temperature compensation circuit that temperature-compensates a detection signal output from each sensor element, a detection circuit that detects angular velocities around the respective axes and accelerations in the respective axis directions based on the temperature-compensated detection signals, and an interface circuit that inputs and outputs various signals.

However, the configurations of the inertial sensor devices 911, 912, and 913 are not particularly limited as long as the devices are 6DoF sensors. Hereinafter, for convenience of description, a surface of each of the inertial sensor devices 911, 912, and 913 mounted on the flexible wiring board 61 is referred to as the “bottom surface”, and a surface opposite to the bottom surface is referred to as the “top surface”. In the embodiment, the bottom surface and the top surface are parallel to each other.

As shown in FIG. 4, the sensor mounting substrate 5 is housed in the base 3 in a state where the flexible wiring board 61 is bent in the thickness direction (Z-axis direction) so as to extend over the region Q1 and the region Q2 beyond the first inner wall portion 331 with the back surface of the flexible wiring board 61 facing downward. As described above, the bendable flexible wiring board 61 is used as the coupling portion 6, and thereby, the attachment of the inertial sensor devices 911, 912, and 913 to the base 3 is easier.

As shown in FIG. 1, when the sensor mounting substrate 5 is housed in the base 3, the circuit element 7 and the connector 8 are respectively located within the region Q1 and joined to the inner bottom surface (the upper surface of the bottom portion 31) of the base 3 via the flexible wiring board 61. Further, the inertial sensor device 913 is located within the region Q1 together with the circuit element 7 and the connector 8, and joined to the wall surface 331b in an attitude in which the top surface thereof faces the wall surface 331b of the first inner wall portion 331 as the third placement surface.

On the other hand, the inertial sensor device 911 is located within the region Q2 and joined to the wall surface 321b in an attitude in which the top surface thereof faces the wall surface 321b of the first outer wall portion 321 as the first placement surface. Further, the inertial sensor device 912 is located within the region Q2 together with the inertial sensor device 911, and joined to the wall surface 331a in an attitude in which the top surface thereof faces the wall surface 331a of the first inner wall portion 331 as the second placement surface. The joining method is not particularly limited, but in the embodiment, the joining is performed using an adhesive.

According to the configuration, since the base 3 includes the wall surfaces 321b, 331a, and 331b parallel to one another, juxtaposition of the inertial sensor devices 911, 912, and 913 in parallel to one another is easier.

As shown in FIG. 5, when the sensor mounting substrate 5 is joined to the base 3, the inertial sensor devices 911, 912, and 913 are disposed in juxtaposition along the X-axis direction. As described above, the inertial sensor devices 911, 912, and 913 are disposed in juxtaposition along the X-axis direction, and thereby, the inertial sensor devices 911, 912, and 913 can be arranged in a row close to one another. Therefore, the inertial detection accuracy of the sensor module 1 can be increased, and the sensor module 1 can be downsized.

The inertial sensor devices 911, 912, and 913 are disposed in attitudes with the detection axes aligned with one another. In the illustrated configuration, each of the inertial sensor devices 911, 912, and 913 is disposed in an attitude in which the J1 axis is along the Z-axis direction, the J2 axis is along the Y-axis direction, and the J3 axis is along the X-axis direction. In particular, in the embodiment, the inertial sensor devices 911, 912, and 913 are disposed so that the centers thereof are located in the same straight line along the X-axis direction. Note that, in the embodiment, each of the inertial sensor devices 911 and 913 is in an attitude with the top surface facing the minus side in the X-axis direction, whereas the inertial sensor device 912 is in an attitude with the top surface facing the plus side in the X-axis direction. That is, the inertial sensor device 912 is in an attitude inverted by 180° around the Y axis with respect to the inertial sensor devices 911 and 913, and as a result, the directions of the J1 axis and the J3 axis are opposite.

The circuit element 7 includes, for example, a drive control circuit that controls driving of the inertial sensor devices 911, 912, and 913, a detection circuit that detects angular velocities around the respective axes and accelerations in the respective axis directions based on detection signals output from the respective inertial sensor devices 911, 912, and 913, and an interface circuit that inputs and outputs various signals. The circuit element 7 obtains, for example, the angular velocity around the J2 axis and the acceleration in the J2-axis direction by averaging three detection signals at the same time received from the respective inertial sensor devices 911, 912, and 913. The angular velocity around the J1 axis, the acceleration in the J1-axis direction, the angular velocity around the J3 axis, and the acceleration in the J3-axis direction are obtained by averaging of the three detection signals at the same time received from the respective inertial sensor devices 911, 912, and 913 with the same positive or negative signs. According to the configuration, noise can be reduced, and the detection accuracy of the angular velocity and the acceleration is increased.

As above, the sensor module 1 is described. As described above, the sensor module 1 includes the first inertial sensor device group 91 including the inertial sensor device 911 as the first inertial sensor device, the inertial sensor device 912 as the second inertial sensor device, and the inertial sensor device 913 as the third inertial sensor device having the detection axes in the same direction as one another, and the base 3 including the wall surface 321b as the first placement surface on which the inertial sensor device 911 is disposed, the wall surface 331a as the second placement surface parallel to the wall surface 321b, on which the inertial sensor device 912 is disposed, and the wall surface 331b as the third placement surface parallel to the wall surface 321b, on which the inertial sensor device 913 is disposed. According to the configuration, since the base 3 includes the wall surfaces 321b, 331a, and 331b parallel to one another, the juxtaposition of the inertial sensor devices 911, 912, and 913 in parallel to one another is easier.

As described above, the wall surfaces 321b, 331a, and 331b are arranged along the normal direction of the wall surface 321b, that is, the X-axis direction. Accordingly, the inertial sensor devices 911, 912, and 913 can be arranged in a row close to one another. Therefore, the inertial detection accuracy of the sensor module 1 can be increased, and the sensor module 1 can be downsized.

As described above, the inertial sensor devices 911, 912, and 913 are arranged along the normal direction of the wall surface 321b, that is, the X-axis direction. Accordingly, the inertial sensor devices 911, 912, and 913 can be arranged in a row close to one another. Therefore, the inertial detection accuracy of the sensor module 1 can be increased, and the sensor module 1 can be downsized.

As described above, the base 3 has the box shape housing the first inertial sensor device group 91, and includes the first outer wall portion 321 as the first wall portion in which one of the pair of wall surfaces 321a and 321b in the front and back relationship faces the outside of the base 3 and the other faces the inside of the base 3, and the first inner wall portion 331 as the second wall portion disposed to face the first outer wall portion 321, in which the pair of wall surfaces 331a and 331b in the front and back relationship face the inside of the base 3. The wall surface 321b of the first outer wall portion 321 facing the inside of the base 3 is the first placement surface, the wall surface 331a of the first inner wall portion 331 facing the first outer wall portion 321 is the second placement surface, and the wall surface 331b of the first inner wall portion 331 located at the side opposite to the first outer wall portion 321 is the third placement surface. According to the configuration, the first placement surface, the second placement surface, and the third placement surface can be provided in the base 3 with a simple configuration.

As described above, the sensor module 1 includes the coupling portion 6 that couples the inertial sensor devices 911, 912, and 913. According to the configuration, since the inertial sensor devices 911, 912, and 913 are not separated, the attachment of the inertial sensor devices 911, 912, and 913 to the base 3 is easier.

As described above, the coupling portion 6 is the flexible wiring board 61. According to the configuration, the positions and attitudes of the inertial sensor devices 911, 912, and 913 can be easily changed by bending of the flexible wiring board 61. Therefore, the attachment of the inertial sensor devices 911, 912, and 913 to the base 3 is easier.

As above, the sensor module 1 is described, however, the configuration of the sensor module 1 is not particularly limited.

For example, the number of inertial sensor devices of the first inertial sensor device group 91 is not limited to three, but may be four or more. In the example shown in FIG. 6, the first inertial sensor device group 91 includes five inertial sensor devices 911, 912, 913, 914, and 915. In this case, a pair of the first inner wall portions 331 may be formed in juxtaposition in the X-axis direction in the base 3, and both wall surfaces of the first inner wall portions 331 located at the plus side in the X-axis direction may be used as placement surfaces for the inertial sensor devices 914 and 915.

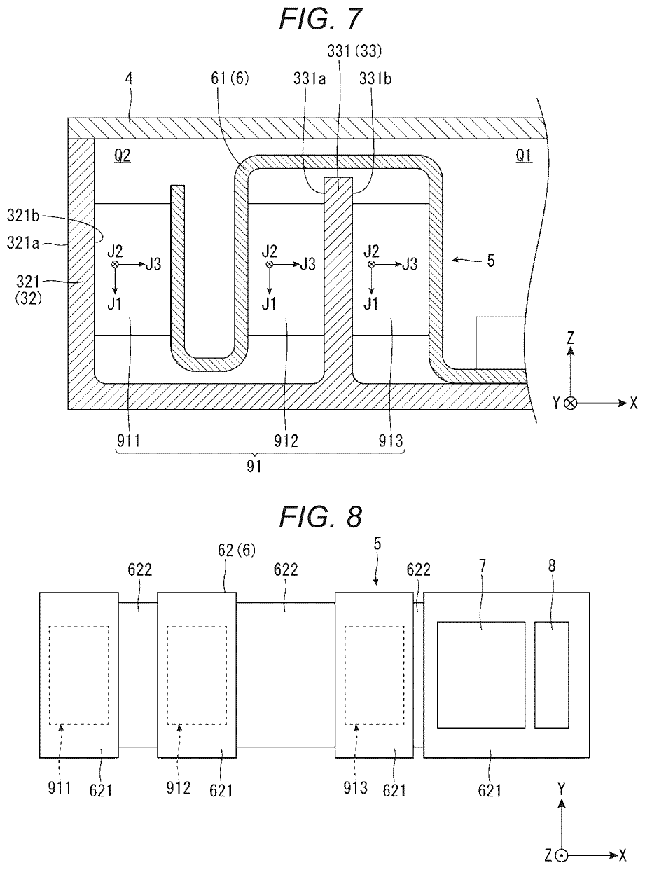

For example, as shown in FIG. 7, all of the inertial sensor devices 911, 912, and 913 may be oriented in the same direction. In this case, the inertial sensor device 912 may be mounted on the flexible wiring board 61 in an attitude inverted with respect to that of the embodiment.

As described above, the first inertial sensor devices 911, 912, and 913 have the detection axes in the same direction as one another, however, all the detection axes may be oriented in the same direction as shown in FIG. 7, or part of the detection axes may be oriented toward the opposite side to the other detection axes as shown in FIG. 5. That is, when a certain direction is a positive direction and the opposite direction is a negative direction, the detection axes in the same direction as each other may include detection axes only in the positive direction, detection axes only in the negative direction, and both a detection axis in the positive direction and a detection axis in the negative direction.

For example, each of the inertial sensor devices 911, 912, and 913 is not necessarily the 6DoF sensor. In this case, for example, the inertial sensor devices 911, 912, and 913 may be single-axis angular velocity sensors that detect angular velocities around the J1 axis, and the J1 axis of each of the inertial sensor devices 911, 912, and 913 may be set along any direction of the X axis, the Y axis, and the Z axis. For example, the inertial sensor devices 911, 912, and 913 may be three-axis angular velocity sensors that detect angular velocities around the J1 axis, the J2 axis, and the J3 axis, and the J1 axis, the J2 axis, and the J3 axis of each of the inertial sensor devices 911, 912, and 913 may be set along the Z-axis direction, the Y-axis direction, and the Z-axis direction, respectively.

For example, the inertial sensor devices 911, 912, and 913 may be single-axis acceleration sensors that detect accelerations in the J1 axis direction, and the J1 axis of each of the inertial sensor devices 911, 912, and 913 may be set along any direction of the X axis, the Y axis, and the Z axis. For example, the inertial sensor devices 911, 912, and 913 may be three-axis acceleration sensors that detect accelerations in the respective axis directions of the J1 axis, the J2 axis, and the J3 axis, and the J1 axis, the J2 axis, and the J3 axis of each of the inertial sensor devices 911, 912, and 913 may be set along the Z-axis direction, the Y-axis direction, and the Z-axis direction, respectively.

Note that the configuration of the coupling portion 6 is not particularly limited. For example, as shown in FIG. 8, the coupling portion 6 may be a rigid flexible wiring board 62 formed by coupling of a plurality of rigid wiring boards 621 by a plurality of flexible wiring boards 622. In the illustrated example, the rigid flexible wiring board 62 includes the rigid wiring board 621 on which the inertial sensor device 911 is mounted, the rigid wiring board 621 on which the inertial sensor device 912 is mounted, the rigid wiring board 621 on which the inertial sensor device 913 is mounted, and the rigid wiring board 621 on which the circuit element 7 and the connector 8 are mounted, and these are coupled via the flexible wiring boards 622. In the above described configuration, the flexible wiring boards 622 are bended, and thereby, the sensor mounting substrate 5 can be disposed in the base 3 in the same manner as that in the embodiment.

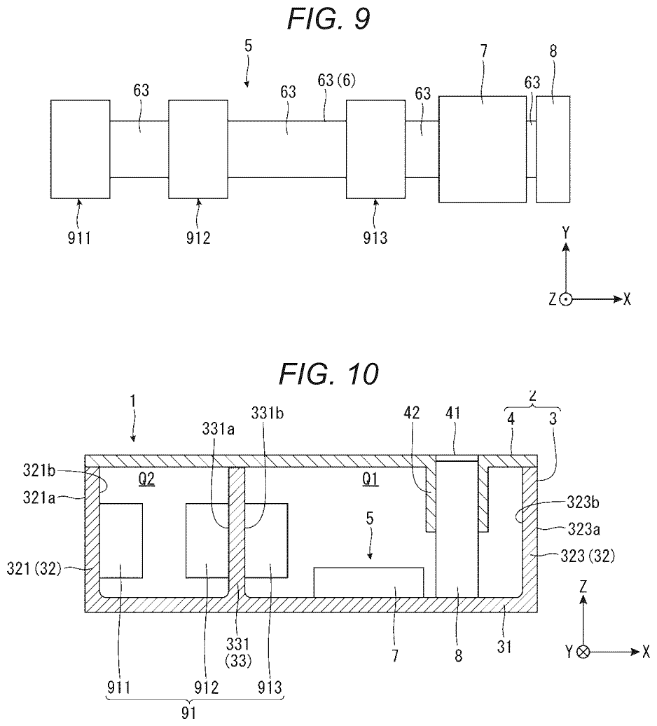

Further, for example, as shown in FIG. 9, the coupling portion 6 may be a connector wire 63. The connector wire 63 includes connectors at both ends, and electrically couples two objects by coupling each connector to the object. In the illustrated example, the coupling portion 6 includes the connector wire 63 coupling the inertial sensor devices 911 and 912, the connector wire 63 coupling the inertial sensor devices 912 and 913, the connector wire 63 coupling the inertial sensor device 913 and the circuit element 7, and the connector wire 63 coupling the circuit element 7 and the connector 8.

For example, as shown in FIG. 10, the coupling portion 6 may be omitted.

### Second Embodiment

FIG. 11 is a cross-sectional view showing a sensor module according to a second embodiment.

The embodiment is the same as the above described first embodiment except that the configuration of the sensor mounting substrate 5 is different. In the following description, the embodiment will be described with a focus on the differences from the above described first embodiment, and the description of the same matters will be omitted. In the drawings of the embodiment, the same configurations as those of the above described embodiment have the same signs.

As shown in FIG. 11, in the sensor mounting substrate 5 of the embodiment, all of the circuit element 7, the connector 8, and the inertial sensor devices 911, 912, and 913 are mounted on the front surface of the flexible wiring board 61. The sensor mounting substrate 5 is housed in the base 3 in a state where the flexible wiring board 61 is bent in the thickness direction so as to extend over the region Q1 and the region Q2 beyond the first inner wall portion 331 with the back surface facing downward.

The circuit element 7 and the connector 8 are located within the region Q1 and joined to the inner bottom surface of the base 3 via the flexible wiring board 61. Further, the inertial sensor device 913 is located within the region Q1 together with the circuit element 7 and the connector 8, and joined to the wall surface 331b via the flexible wiring board 61 in an attitude in which the bottom surface thereof faces the wall surface 331b of the first inner wall portion 331.

On the other hand, the inertial sensor device 911 is located within the region Q2 and joined to the wall surface 321b via the flexible wiring board 61 in an attitude in which the bottom surface thereof faces the wall surface 321b of the first outer wall portion 321. Further, the inertial sensor device 912 is located within the region Q2 together with the inertial sensor device 911, and joined to the wall surface 331a via the flexible wiring board 61 in an attitude in which the bottom surface thereof faces the wall surface 331a of the first inner wall portion 331.

According the second embodiment, the same effects as those of the above described first embodiment can be exerted.

### Third Embodiment

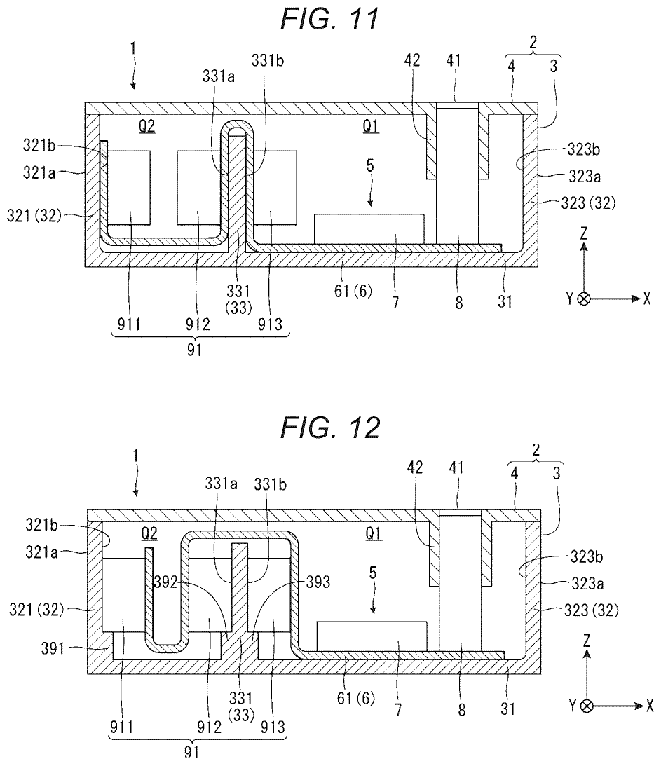

FIG. 12 is a cross-sectional view showing a sensor module according to a third embodiment. FIG. 13 is a front view of a first positioning portion.

The embodiment is the same as the above described first embodiment except that the configuration of the base 3 is different. In the following description, the embodiment will be described with a focus on the differences from the above described first embodiment, and the description of the same matters will be omitted. In the respective drawings of the embodiment, the same configurations as those in the above described embodiments have the same signs.

As shown in FIG. 12, the base 3 of the embodiment includes a first positioning portion 391 that positions the inertial sensor device 911 with respect to the wall surface 321b, a second positioning portion 392 that positions the inertial sensor device 912 with respect to the wall surface 331a, and a third positioning portion 393 that positions the inertial sensor device 913 with respect to the wall surface 331b. According to the configuration, shifts in position and attitude of the inertial sensor devices 911, 912, and 913 can be effectively suppressed.

As shown in FIG. 13, the first positioning portion 391 projects from the wall surface 321b, and has a contact surface 391a in contact with the side surface of the inertial sensor device 911 facing the minus side in the Z-axis direction, and a contact surface 391b in contact with the side surface of the inertial sensor device 911 facing the plus side in the Y-axis direction. According to the configuration, shifts in position and attitude of the inertial sensor device 911 can be suppressed with a simple configuration. However, the configuration of the first positioning portion 391 is not particularly limited. Since the second and third positioning portions 392 and 393 have the same configuration as the first positioning portion 391, the description thereof will be omitted.

According the third embodiment, the same effects as those of the above described first embodiment can be exerted.

### Fourth Embodiment

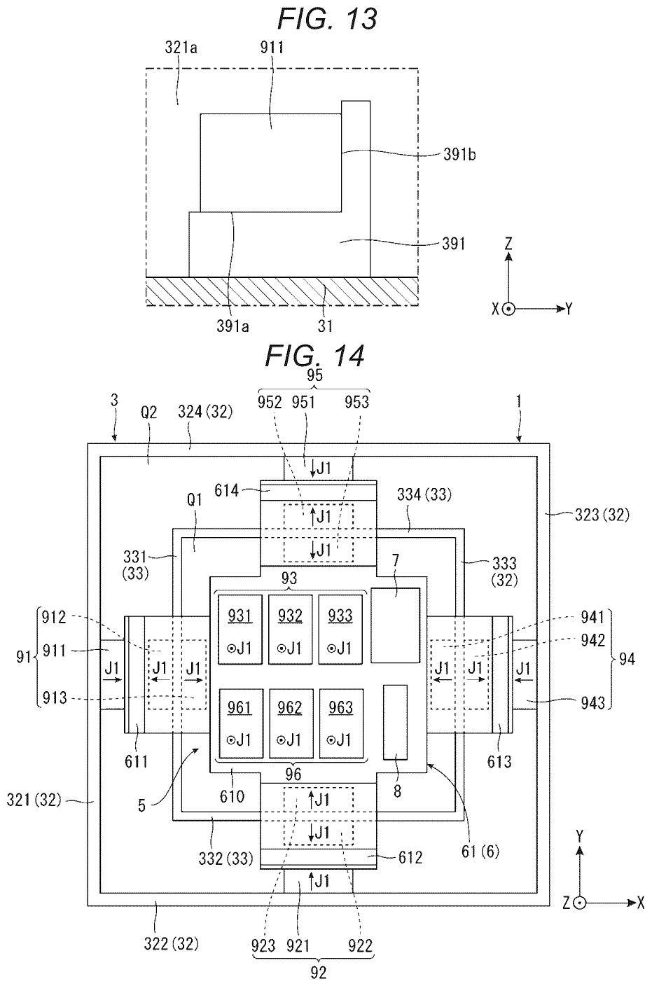

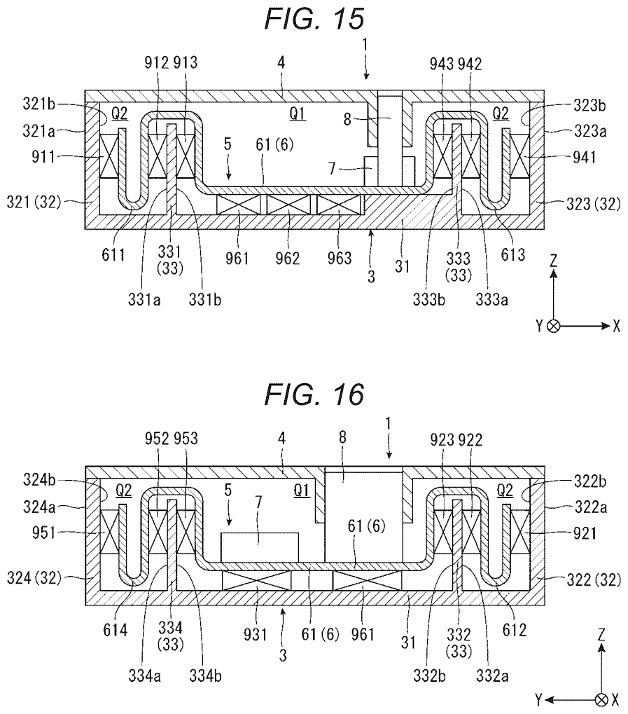

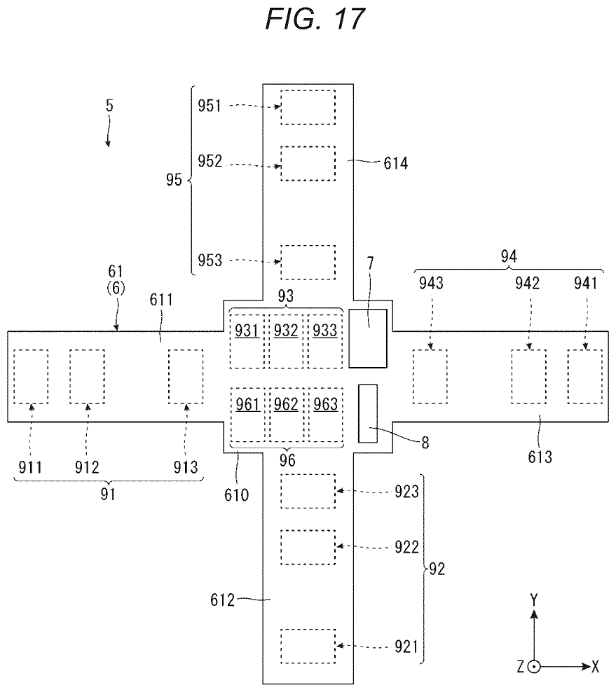

FIG. 14 is a top view showing a sensor module according to a fourth embodiment. FIGS. 15 and 16 are respectively cross-sectional views of the sensor module shown in FIG. 14. FIG. 17 is a development view of a sensor mounting substrate.

The embodiment is the same as the above described first embodiment except that the configurations of the base 3 and the sensor mounting substrate 5 are different. In the following description, the embodiment will be described with a focus on the differences from the above described first embodiment, and the description of the same matters will be omitted. In the respective drawings of the embodiment, the same configurations as those in the above described embodiments have the same signs.

As shown in FIG. 14, in the base 3 of the embodiment, the inner wall portion 33 has a rectangular frame shape. The inner wall 33 includes the first inner wall portion 331 located at the minus side in the X-axis direction and extending in the Y-axis direction, a second inner wall portion 332 located at the minus side in the Y-axis direction and extending in the X-axis direction, a third inner wall portion 333 located at the plus side in the X-axis direction and extending in the Y-axis direction, and a fourth inner wall portion 334 located at the plus side in the Y-axis direction and extending in the X-axis direction. The inner wall portion 33 is formed concentrically with the outer wall portion 32.

As shown in FIG. 15, the first inner wall portion 331 has the pair of wall surfaces 331a and 331b in a front and back relationship, and faces the inside of the base 3. One wall surface 331a (at the minus side in the X-axis direction) faces the first outer wall portion 321, and the other wall surface 331b (at the plus side in the X-axis direction) faces the third inner wall portion 333. The third inner wall portion 333 has a pair of wall surfaces 333a and 333b in a front and back relationship, and both face the inside of the base 3. One wall surface 333a (at the plus side in the X-axis direction) faces the third outer wall portion 323, and the other wall surface 333b (at the minus side in the X-axis direction) faces the first inner wall portion 331.

As shown in FIG. 16, the second inner wall portion 332 has a pair of wall surfaces 332a and 332b in a front and back relationship, and both face the inside of the base 3. One wall surface 332a (at the minus side in the Y-axis direction) faces the second outer wall portion 322, and the other wall surface 332b (at the plus side in the Y-axis direction) faces the fourth inner wall portion 334. The fourth inner wall portion 334 has a pair of wall surfaces 334a and 334b in a front and back relationship, and both face the inside of the base 3. One wall surface 334a (at the plus side in the Y-axis direction) faces the fourth outer wall portion 324, and the other wall surface 334b (at the minus side in the Y-axis direction) faces the second inner wall portion 332.

As shown in FIG. 15, each of the six wall surfaces 321b, 331a, 331b, 333b, 333a, and 323b arranged along the X-axis direction includes the Y-Z plane orthogonal to the X axis. That is, the wall surfaces 321b, 331a, 331b, 333b, 333a, and 323b are parallel to one another. Similarly, as shown in FIG. 16, each of the six wall surfaces 322b, 332a, 332b, 334b, 334a, and 324b arranged along the Y-axis direction includes an X-Z plane orthogonal to the Y axis. That is, the wall surfaces 322b, 332a, 332b, 334b, 334a, and 324b are parallel to one another.

As shown in FIG. 14, the sensor mounting substrate 5 includes a second inertial sensor device group 92, a third inertial sensor device group 93, a fourth inertial sensor device group 94, a fifth inertial sensor device group 95, and a sixth inertial sensor device group 96 in addition to the circuit element 7, the connector 8, and the first inertial sensor device group 91.

The first inertial sensor device group 91 includes the inertial sensor devices 911, 912, and 913 like that in the above described embodiment. The second inertial sensor device group 92 includes an inertial sensor device 921 as a fourth inertial sensor device, an inertial sensor device 922 as a fifth inertial sensor device, and an inertial sensor device 923 as a sixth inertial sensor device. The third inertial sensor device group 93 includes inertial sensor devices 931, 932, and 933.

These inertial sensor devices 911, 912, 913, 921, 922, 923, 931, 932, and 933 have the same configuration and each is a single-axis angular velocity sensor that detects an angular velocity around the J1 axis. The inertial sensor devices 911, 912, and 913, the inertial sensor devices 921, 922, and 923, and the inertial sensor devices 931, 932, and 933 are housed in the base 3 in attitudes orthogonal to one another. Specifically, each of the inertial sensor devices 911, 912, and 913 is housed in the base 3 in an attitude in which the J1 axis is aligned with the X axis. Each of the inertial sensor devices 921, 922, and 923 is housed in the base 3 in an attitude in which the J1 axis is aligned with the Y axis. Each of the inertial sensor devices 931, 932, and 933 is housed in the base 3 in an attitude in which the J1 axis is aligned with the Z axis.

The fourth inertial sensor device group 94 includes inertial sensor devices 941, 942, and 943. The fifth inertial sensor device group 95 includes inertial sensor devices 951, 952, and 953. The sixth inertial sensor device group 96 includes inertial sensor devices 961, 962, and 963.

The inertial sensor devices 941, 942, 943, 951, 952, 953, 961, 962, and 963 have the same configuration, and each is a single-axis acceleration sensor that detects an acceleration in the J1 axis direction. The inertial sensor devices 941, 942, and 943, the inertial sensor devices 951, 952, and 953, and the inertial sensor devices 961, 962, and 963 are housed in the base 3 in attitudes orthogonal to one another. Specifically, each of the inertial sensor devices 941, 942, and 943 is housed in the base 3 in an attitude in which the J1 axis is aligned with the X axis. Each of the inertial sensor devices 951, 952, and 953 is housed in the base 3 in an attitude in which the J1 axis is aligned with the Y axis. Each of the inertial sensor devices 961, 962, and 963 is housed in the base 3 in an attitude in which the J1 axis is aligned with the Z axis.

FIG. 17 is a development view of the flexible wiring board 61. As shown in the drawing, the flexible wiring board 61 has a cross shape, and includes a center portion 610 located at the center, a first strip portion 611 extending from the center portion 610 to the minus side in the X-axis direction, a second strip portion 612 extending from the center portion 610 to the minus side in the Y-axis direction, a third strip portion 613 extending from the center portion 610 to the plus side in the X-axis direction, and a fourth strip portion 614 extending from the center portion 610 to the plus side in the Y-axis direction.

The circuit element 7 and the connector 8 are mounted on the front surface of the center portion 610, and the inertial sensor devices 931, 932, 933, 961, 962, and 963 are mounted on the back surface of the center portion 610. The inertial sensor devices 931, 932, and 933 are disposed in juxtaposition in the X-axis direction. Similarly, the inertial sensor devices 961, 962, and 963 are disposed in juxtaposition in the X-axis direction.

The inertial sensor devices 911, 912, and 913 are mounted in juxtaposition in the X-axis direction on the back surface of the first strip portion 611. The inertial sensor devices 921, 922, and 923 are mounted in juxtaposition in the Y-axis direction on the back surface of the second strip portion 612. The inertial sensor devices 941, 942, and 943 are mounted in juxtaposition in the X-axis direction on the back surface of the third strip portion 613. The inertial sensor devices 951, 952, and 953 are mounted in juxtaposition in the Y-axis direction on the back surface of the fourth strip portion 614.

The sensor mounting substrate 5 is housed in the base 3 in a state where the first, second, third, and fourth strip portions 611, 612, 613, and 614 are bent in the thickness direction so that the first, second, third, and fourth strip portions 611, 612, 613, and 614 extend over the region Q1 and the region Q2 beyond the inner wall portion 33 with the back surface of the flexible wiring board 61 facing downward and the center portion 610 disposed within the region Q1.

As shown in FIG. 15, the circuit element 7 and the connector 8 are located within the region Q1 and are joined to the inner bottom surface of the base 3 via the flexible wiring board 61. Each of the inertial sensor devices 931, 932, 933, 961, 962, and 963 is located within the region Q1 and joined to the inner bottom surface of the base 3 in an attitude in which the top surface thereof faces the inner bottom surface of the base 3. In the embodiment, the portion where the circuit element 7 and the connector 8 are disposed is raised by the thickness of the inertial sensor devices 931, 932, 933, 961, 962, and 963 to suppress the bending of the center portion 610.

As shown in FIG. 15, the inertial sensor device 911 is located within the region Q2 and joined to the wall surface 321b in an attitude in which the top surface thereof faces the wall surface 321b of the first outer wall portion 321. The inertial sensor device 912 is located within the region Q2 and joined to the wall surface 331a in an attitude in which the top surface thereof faces the wall surface 331a of the first inner wall portion 331. The inertial sensor device 913 is located within the region Q1 and joined to the wall surface 331b in an attitude in which the top surface thereof faces the wall surface 331b of the first inner wall portion 331.

As shown in FIG. 16, the inertial sensor device 921 is located within the region Q2 and joined to the wall surface 322b in an attitude in which the top surface thereof faces the wall surface 322b of the second outer wall portion 322 as a fourth placement surface. The inertial sensor device 922 is located within the region Q2 and joined to the wall surface 332a in an attitude in which the top surface thereof faces the wall surface 332a of the second inner wall portion 332 as a fifth placement surface. The inertial sensor device 923 is located within the region Q1 and joined to the wall surface 332b in an attitude in which the top surface thereof faces the wall surface 332b of the second inner wall portion 332 as a sixth placement surface.

As shown in FIG. 15, the inertial sensor device 941 is located within the region Q2 and joined to the wall surface 323b in an attitude in which the top surface thereof faces the wall surface 323b of the third outer wall portion 323. The inertial sensor device 942 is located within the region Q2 and joined to the wall surface 333a in an attitude in which the top surface thereof faces the wall surface 333a of the third inner wall portion 333. The inertial sensor device 943 is located within the region Q1 and joined to the wall surface 333b in an attitude in which the top surface thereof faces the wall surface 333b of the third inner wall portion 333.

As shown in FIG. 16, the inertial sensor device 951 is located within the region Q2 and joined to the wall surface 324b in an attitude in which the top surface thereof faces the wall surface 324b of the fourth outer wall portion 324. The inertial sensor device 952 is located within the region Q2 and joined to the wall surface 334a in an attitude in which the top surface thereof faces the wall surface 334a of the fourth inner wall portion 334. The inertial sensor device 953 is located within the region Q1 and joined to the wall surface 334b in an attitude in which the top surface thereof faces the wall surface 334b of the fourth inner wall portion 334.

All of the inertial sensor devices 911, 912, 913, 921, 922, 923, 931, 932, 933, 941, 942, 943, 951, 952, 953, 961, 962, and 963 may be single-axis angular velocity sensors that detect angular velocities around the J1 axis, single-axis acceleration sensors that detect accelerations in the J1-axis direction, 6DoF sensors, three-axis angular velocity sensors that detect angular velocities around each of the J1 axis, the J2 axis, and the J3 axis, or three-axis acceleration sensors that detect accelerations in directions of each of the J1 axis, the J2 axis, and the J3 axis.

As described above, the sensor module 1 of the embodiment has the second inertial sensor device group 92 including the inertial sensor device 921 as the fourth inertial sensor device, the inertial sensor device 922 as the fifth inertial sensor device, and the inertial sensor device 923 as the sixth inertial sensor device having the detection axes in the same direction as one another. The base 3 includes the wall surface 322b as the fourth placement surface on which the inertial sensor device 921 is disposed, the wall surface 332a as the fifth placement surface parallel to the wall surface 322b, on which the inertial sensor device 922 is disposed, and the wall surface 332b as the sixth placement surface parallel to the wall surface 322b, on which the inertial sensor device 923 is disposed. According to the configuration, since the base 3 includes the wall surfaces 322b, 332a, and 332b parallel to one another, the juxtaposition of the inertial sensor devices 921, 922, and 923 in parallel to one another is easier.

According the fourth embodiment, the same effects as those of the above described first embodiment can be exerted.

### Fifth Embodiment

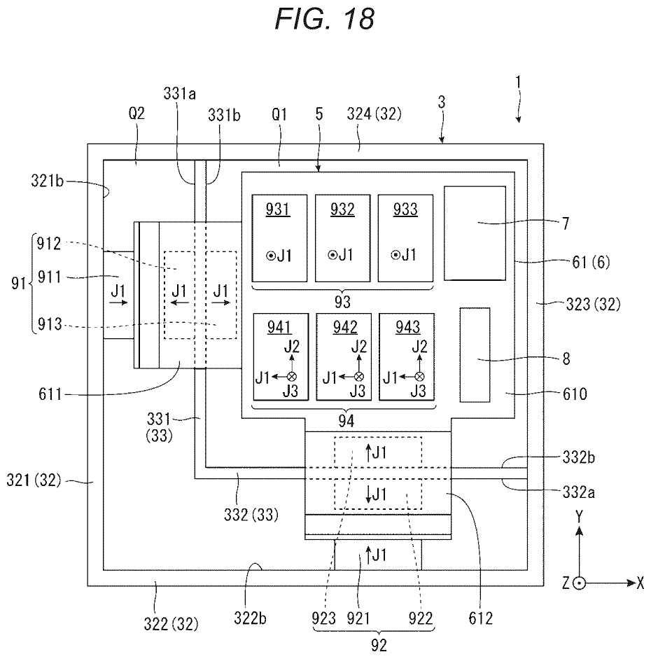

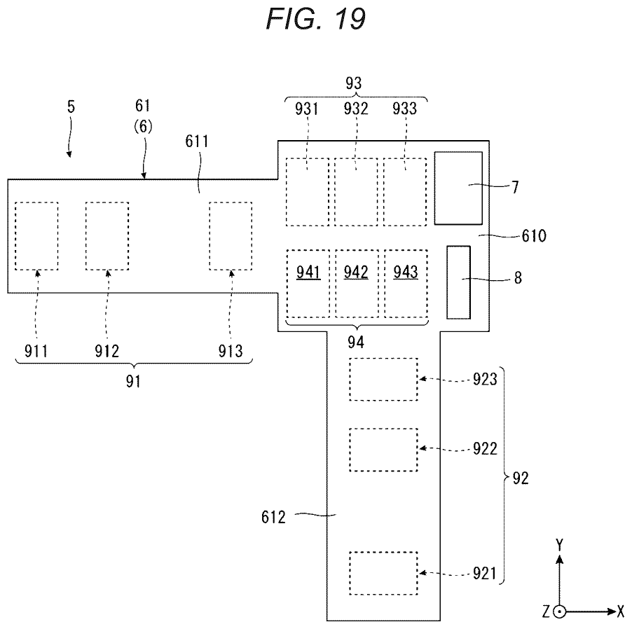

FIG. 18 is a top view showing a sensor module according to a fifth embodiment, a FIG. 19 shows development view of a sensor mounting substrate.

The embodiment is the same as the above described fourth embodiment except that the configurations of the base 3 and the sensor mounting substrate 5 are different. In the following description, the embodiment will be described with a focus on the differences from the above described first embodiment, and the description of the same matters will be omitted. In the respective drawings of the embodiment, the same configurations as those in the above described embodiments have the same signs.

As shown in FIG. 18, in the base 3 of the embodiment, the inner wall portion 33 has an L shape. The inner wall portion 33 includes the first inner wall portion 331 located at the minus side in the X-axis direction and extending in the Y-axis direction, and the second inner wall portion 332 located at the minus side in the Y-axis direction and extending in the X-axis direction.

The sensor mounting substrate 5 includes the second inertial sensor device group 92, the third inertial sensor device group 93, and the fourth inertial sensor device group 94 in addition to the circuit element 7, the connector 8, and the first inertial sensor device group 91. Of the device groups, the first inertial sensor device group 91, the second inertial sensor device group 92, and the third inertial sensor device group 93 have the same configuration as those of the above described fourth embodiment, and the description thereof will be omitted. On the other hand, the three inertial sensor devices 941, 942, and 943 of the fourth inertial sensor device group 94 are three-axis acceleration sensors that detect accelerations in the respective axis directions of the J1 axis, the J2 axis, and the J3 axis, respectively.

FIG. 19 is a development view of the sensor mounting substrate 5. As shown in the drawing, the flexible wiring board 61 has an L shape, and includes the center portion 610 located at the center, the first strip portion 611 extending from the center portion 610 to the minus side in the X-axis direction, and the second strip portion 612 extending from the center portion 610 to the minus side in the Y-axis direction.

The circuit element 7 and the connector 8 are mounted on the front surface of the center portion 610, and the inertial sensor devices 931, 932, 933, 941, 942, and 943 are mounted on the back surface of the center portion 610. The inertial sensor devices 911, 912, and 913 are mounted in juxtaposition in the X-axis direction on the back surface of the first strip portion 611. The inertial sensor devices 921, 922, and 923 are mounted in juxtaposition in the Y-axis direction on the back surface of the second strip portion 612.

The sensor mounting substrate 5 is housed in the base 3 in a state where the first and second strip portions 611 and 612 are bent in the thickness direction so that the first and second strip portions 611 and 612 extend over the region Q1 and the region Q2 beyond the inner wall portion 33 with the back surface of the flexible wiring board 61 facing downward and the center portion 610 disposed within the region Q1. When the sensor mounting substrate 5 is housed in the base 3, the J1 axes of the inertial sensor devices 941, 942, and 943 are aligned with the X axis, the J2 axes are aligned with the Y axis, and the J3 axes are aligned with the Z axis.

According the fifth embodiment, the same effects as those of the above described first embodiment can be exerted.

As above, the sensor module of the present disclosure is described based on the illustrated embodiments, however, the present disclosure is not limited thereto. The configuration of each unit can be replaced with any configuration having the same function. Further, any other configuration may be added to the present disclosure. Furthermore, the respective embodiments may be appropriately combined.

What is claimed is:

1. A sensor module comprising:
a first inertial sensor device group including a first inertial sensor device, a second inertial sensor device, and a third inertial sensor device having detection axes in a same direction as one another; and
a base including a first placement surface on which the first inertial sensor device is disposed, a second placement surface parallel to the first placement surface, on which the second inertial sensor device is disposed, and a third placement surface parallel to the first placement surface, on which the third inertial sensor device is disposed.

2. The sensor module according to claim 1, wherein
the first placement surface, the second placement surface, and the third placement surface are arranged along a normal direction of the first placement surface.

3. The sensor module according to claim 2, wherein
the first inertial sensor device, the second inertial sensor device, and the third inertial sensor device are arranged along the normal direction of the first placement surface.

4. The sensor module according to claim 3, wherein
the base has a box shape housing the first inertial sensor device group, and includes a first wall portion in which one of a pair of wall surfaces in a front and back relationship faces an outside of the base and the other faces an inside of the base, and a second wall portion disposed to face the first wall portion, in which both a pair of wall surfaces in a front and back relationship face the inside of the base,
the wall surface of the first wall portion facing the inside of the base is the first placement surface,
the wall surface of the second wall portion facing the first wall portion is the second placement surface, and
the wall surface of the second wall portion located at a side opposite to the first wall portion is the third placement surface.

5. The sensor module according to claim 1, further comprising a coupling portion coupling the first inertial sensor device, the second inertial sensor device, and the third inertial sensor device.

6. The sensor module according to claim 5, wherein
the coupling portion is a flexible wiring board.

7. The sensor module according to claim 1, further comprising a second inertial sensor device group including a fourth inertial sensor device, a fifth inertial sensor device, and a sixth inertial sensor device having detection axes in a same direction as one another, wherein
the base includes a fourth placement surface on which the fourth inertial sensor device is disposed, a fifth placement surface parallel to the fourth placement surface, on which the fifth inertial sensor device is disposed, and a sixth placement surface parallel to the fourth placement surface, on which the sixth inertial sensor device is disposed.

8. A sensor module comprising:
a first inertial sensor device group including a first inertial sensor device, a second inertial sensor device, and a third inertial sensor device; and
a base including a first placement surface on which the first inertial sensor device is disposed, a second placement surface parallel to the first placement surface, on which the second inertial sensor device is disposed, and a third placement surface parallel to the first placement surface, on which the third inertial sensor device is disposed,
wherein the first placement surface, the second placement surface, and the third placement surface are arranged along a normal direction of the first placement surface.

9. The sensor module according to claim 8, wherein
the first inertial sensor device, the second inertial sensor device, and the third inertial sensor device are arranged along the normal direction of the first placement surface.
